(19) United States
(12) Patent Application Publication
(10) Pub. No.: US 2015/0323158 A1
(43) Pub. Date: Nov. 12, 2015

(54) LIGHT EMITTING DEVICE

(71) Applicant: PIONEER CORPORATION, Kawasaki-shi, Kanagawa (JP)

(72) Inventor: Kazuo KURODA, Kawasaki-shi, Kanagawa (JP)

(73) Assignee: PIONEER CORPORATION, Kawasaki-shi, Kanagawa (JP)

(21) Appl. No.: 14/762,187

(22) PCT Filed: Jan. 25, 2013
(86) PCT No.: PCT/JP2013/051623

§ 371 Date: Jul. 20, 2015

(51) Int. Cl. F21V 14/00; F21V 19/00

(52) U.S. Cl. CPC F21V 14/003; F21V 19/00; F21Y 2113/002

(57) ABSTRACT

A light emitting device (10) includes a light transmissive substrate (110: a light transmissive layer), a light emission unit (130), a light extraction layer (150), and a light transmission quantity adjustment unit (200). The light emission unit (130) is formed on a first surface side of the light transmissive substrate (110). The light transmission quantity adjustment unit (200) is disposed on a side opposite to the light transmissive substrate (110) based on the light emission unit (130), and adjusts a light transmission quantity according to a signal input from the outside. The light extraction layer (150) is disposed on a second surface side of the light transmissive substrate (110). The light emitting device (10), for example, is used as a light source of an illuminating device or a light source of an optical communication device.

### TECHNICAL FIELD

The present invention relates to a light emitting device.

### BACKGROUND ART

Recently, an Organic Electroluminescence (EL) element or a Light Emitting Diode (LED) has been increasingly used as a light source of a light emitting device.

For example, Patent Document 1 discloses that an organic layer is used as an example of a light emitting layer of a light emitting panel. Further, Patent Document 1 discloses that optical films are disposed on both surfaces of the light emitting panel from which light is emitted. In the optical films, polarization directions of light to be transmitted intersect with each other. Accordingly, it is disclosed that a background of the light emitting panel is able to be prevented from being transparently viewed through.

In addition, in Patent Document 2, a display device is disclosed in which a transmissive liquid crystal panel is arranged on a light source which includes a red LED, a green LED, and a blue LED. Further, Patent Document 2 discloses that, when light emission intensity of the LED is calibrated, the red LED, the green LED, and the blue LED are subjected to time division and are driven.

### RELATED DOCUMENT

### Patent Document

[Patent Document 1] Japanese Unexamined Patent Application Publication No. 2005-191015
[Patent Document 2] Japanese Unexamined Patent Application Publication No. 2007-265984

### SUMMARY OF THE INVENTION

When a light-transmissive surface light emission unit is used as the light source, the light is emitted from both surfaces of the surface light emission unit. In addition, as disclosed in Patent Document 1, a background of the surface light emission unit is transparently viewed through according to a usage mode. In such a case, the present inventors have considered that, when light transmissivity of one surface of the surface light emission unit is variable, use of the light emitting device is widened.

An example of an object of the present invention includes, widening the use of the light emitting device.

The invention according to claim 1 is a light emitting device including a light transmissive layer, a light emission unit which is formed on a first surface side of the light transmissive layer, a light transmission quantity adjustment unit which is disposed on a side opposite to the light transmissive layer based on the light emission unit, and adjusts a light transmission quantity according to a signal input from the outside, and a light extraction layer which is disposed on a second surface side of the light transmissive layer.

The invention according to claim 3 is a light emitting device including a light-transmissive surface light emission unit, a light transmission quantity adjustment unit which is disposed on one surface side of the surface light emission unit, and controls emission of light from the surface light emission unit, and a control unit which controls the light transmission quantity adjustment unit based on a timing at which the surface light emission unit emits light.

### BRIEF DESCRIPTION OF THE DRAWINGS

The object described above, and other objects, characteristics, and advantages will become more obvious with reference to the following preferred embodiments and the following drawings attached thereto.

FIG. 1 is a diagram illustrating a configuration of a light emitting device according to Embodiment 1.

FIG. 2 is a diagram illustrating a configuration of a light emitting device according to Embodiment 2.

FIG. 3 is a diagram illustrating a configuration of a light emitting device according to Example 1.

FIG. 4 is a diagram illustrating a first example of controlling a light transmission quantity adjustment unit by a control unit.

FIG. 5 is a diagram illustrating a second example of controlling the light transmission quantity adjustment unit by the control unit.

FIG. 6 is a diagram illustrating a configuration of a light emitting device according to Example 2.

### DESCRIPTION OF EMBODIMENTS

Hereinafter, embodiments of the present invention will be described with reference to the drawings. Furthermore, in all of the drawings, the same reference numerals are applied to the same constituent parts, and the description thereof will not be repeated.

Furthermore, in the following description, a control unit 300 does not have a configuration of a hardware unit, and illustrates a block of a functional unit. Each constituent of the control unit 300 is realized by a CPU of an arbitrary computer, a memory, a program which is loaded in the memory and realizes the constituent illustrated in this drawing, a storage medium such as a hard disk which stores the program, and an arbitrary combination of hardware and software based on an interface for network connection. Then, a realizing method and a device thereof include various modification examples.

### Embodiment 1

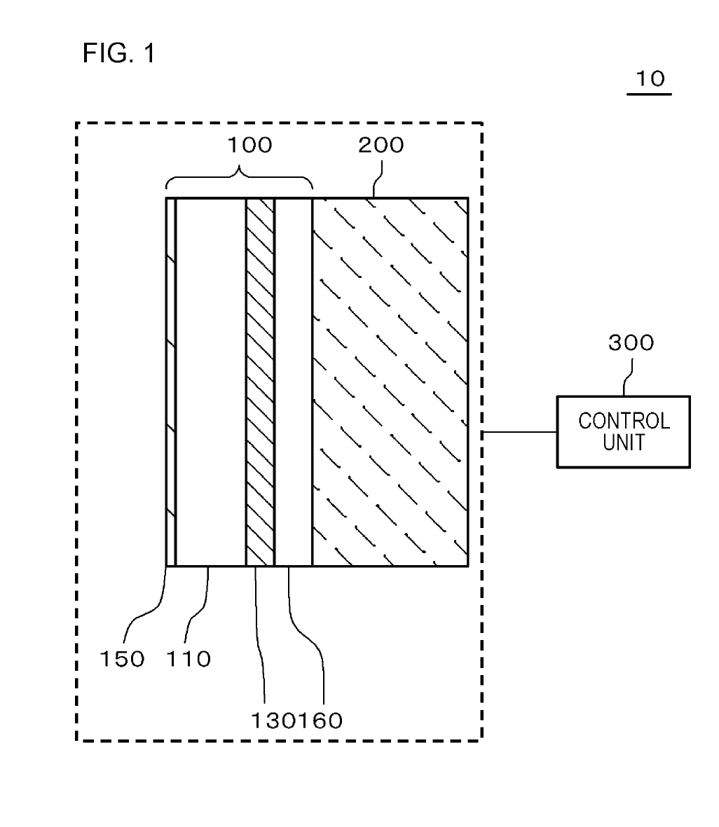

FIG. 1 is a diagram illustrating a configuration of a light emitting device 10 according to Embodiment 1. The light emitting device 10, for example, is used as a light source of an illuminating device or a light source of an optical communication device. The light emitting device 10 according to this embodiment includes a light transmissive substrate 110 (a light transmissive layer), a light emission unit 130, a light extraction layer 150, and a light transmission quantity adjustment unit 200. The light emission unit 130 is formed on a first surface side of the light transmissive substrate 110. The light transmission quantity adjustment unit 200 is disposed on a side opposite to the light transmissive substrate 110 based on the light emission unit 130, and adjusts a light transmission quantity according to a signal input from the outside. The light extraction layer 150 is disposed on a second surface side of the light transmissive substrate 110. Then, at least a part of a surface light emission unit 100 is formed by the light transmissive substrate 110, the light emission unit 130, and the light extraction layer 150.

The light transmissive substrate 110, for example, is formed of glass or a resin material. In a case where the light transmissive substrate 110 is formed of a resin material, when the light transmissive substrate 110 is thinned into the shape of a film, it is possible to impart flexibility to the surface light emission unit 100.

The light emission unit 130, for example, is an organic EL, and may be a LED or other light sources. The light emission unit 130 is formed on the light transmissive substrate 110. A layer configuring the light emission unit 130 has light transmissivity.

A protection layer 160 is disposed between the light emission unit 130 and the light transmission quantity adjustment unit 200. The protection layer 160 is disposed in order to protect the light emission unit 130, and is formed of a light transmissive insulating material. The protection layer 160, for example, is a resin such as Polyethylene terephthalate (PET) or Polyethylene naphthalate (PEN).

The light extraction layer 150 is disposed in order to improve a ratio of emitting light (light extraction efficiency) from the light transmissive substrate 110. The light extraction layer 150, for example, is a light extraction film. In order to prevent a background from being transparently viewed through, a light extraction film having a high diffusion effect may be used, and in contrast, in order to allow the background to be transparently viewed through, for example, an antireflection film having a moth-eye structure may be used.

Furthermore, in an example illustrated in this drawing, the light emission unit 130 is formed on the first surface of the light transmissive substrate 110, and the light extraction layer 150 is formed on the second surface of the light transmissive substrate 110. However, other layers or patterns may be formed between the light transmissive substrate 110 and the light emission unit 130, and other layers or patterns may be formed between the light extraction layer 150 and the light transmissive substrate 110.

In addition, the light transmission quantity adjustment unit 200 is disposed on a side opposite to the light emission unit 130 of the protection layer 160, and a space or other layers may be disposed between the light transmission quantity adjustment unit 200 and the protection layer 160.

In addition, in the example of this drawing, the light emitting device 10 includes the control unit 300. The control unit 300 controls the light transmission quantity adjustment unit 200 based on a timing at which the surface light emission unit 100 emits light.

The light transmission quantity adjustment unit 200, for example, includes a liquid crystal. In this case, the light transmission quantity adjustment unit 200 controls an alignment direction of the liquid crystal, and thus a light transmission quantity of the light transmission quantity adjustment unit 200 is controlled. However, the light transmission quantity adjustment unit 200 may control the light transmission quantity by using other methods, for example, by using a shutter which is driven by a Micro Electro Mechanical System (MEMS).

According to this embodiment, the light transmissive substrate 110 has light transmissivity, and thus the light from the light emission unit 130 is emitted to the outside through the light transmissive substrate 110. In particular, in this embodiment, the light extraction layer 150 is disposed on the second surface side of the light transmissive substrate 110, and thus light extraction efficiency from the second surface side of the light transmissive substrate 110 increases. Then, the light transmission quantity adjustment unit 200 is disposed on the first surface side of the light transmissive substrate 110. For this reason, it is possible to restrict light transmission quantity of the first surface side of the light transmissive substrate 110 at a desired timing. For this reason, it is possible to widen the use of the light emitting device 10.

In particular, in this embodiment, the control unit 300 controls the light transmission quantity adjustment unit 200 based on the timing at which the surface light emission unit 100 emits the light. For this reason, it is possible to allow the light from the surface light emission unit 100 to be emitted or not to be emitted to the first surface side. For this reason, it is possible to widen the use of the light emitting device 10. For example, when the light emitting device 10 is used as the light source of the optical communication device, a light signal is able to be output to each of the first surface side and the second surface side of the light transmissive substrate 110, and the light signal is able to be output only to the second surface side (a side on which the light transmission quantity adjustment unit 200 is not disposed).

### Embodiment 2

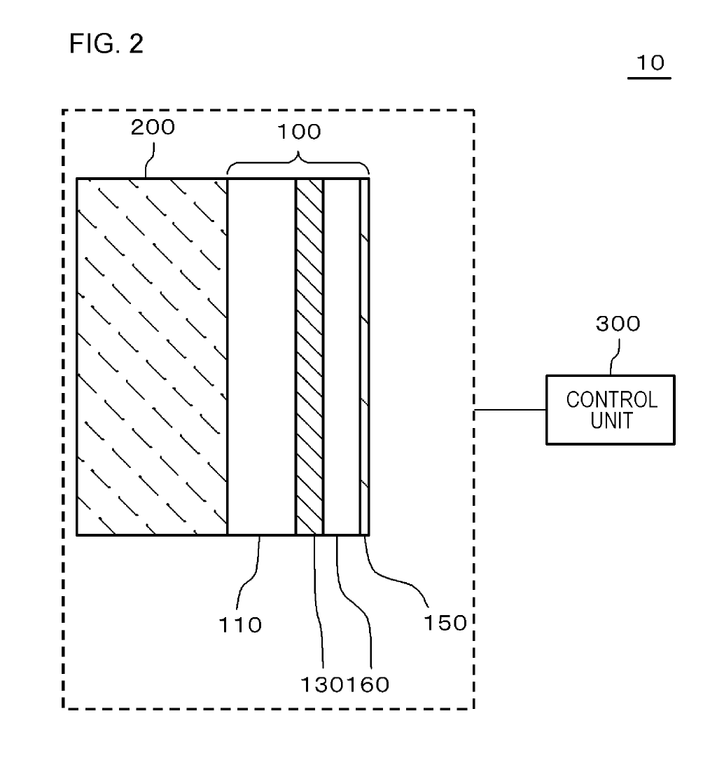

FIG. 2 is a diagram illustrating a configuration of the light emitting device 10 according to Embodiment 2. The light emitting device 10 according to this embodiment has the same configuration as that of the light emitting device 10 according to Embodiment 1 except that the positions of the light transmission quantity adjustment unit 200 and the light extraction layer 150 are reversed. That is, in this embodiment, the light transmission quantity adjustment unit 200 is arranged on the second surface side of the light transmissive substrate 110, and the light extraction layer 150 is attached to a surface of the protection layer 160 on a side opposite to the light emission unit 130. In this embodiment, the protection layer 160 is a light transmissive layer.

In this embodiment, the same effect as that of the embodiment is able to be obtained.

### Example

### Example 1

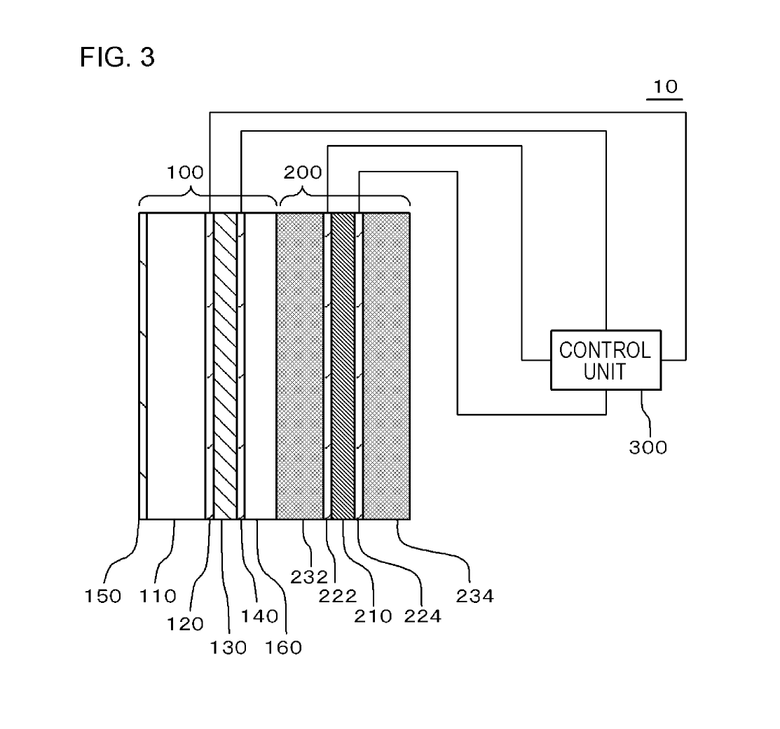

FIG. 3 is a diagram illustrating a configuration of the light emitting device 10 according to Example 1. In this example, the surface light emission unit 100 is an organic EL panel, and the light transmission quantity adjustment unit 200 includes a liquid crystal layer 210.

First, the surface light emission unit 100 will be described. The light emission unit 130 of the surface light emission unit 100 is formed of an organic layer. The organic layer, for example, has a configuration in which a hole injection layer, a hole transport layer, a light emitting layer, an electron transport layer, and an electron injection layer are laminated in this order. However, at least one of the hole transport layer and the electron transport layer may be omitted. In addition, each layer configuring the organic layer may be formed by a coating method, or may be formed by a vapor deposition method. In addition, it is not necessary that all of the respective layers are formed by the same method.

The light emission unit 130 is interposed between a first electrode 120 and a second electrode 140. Both of the first electrode 120 and the second electrode 140 have light transmissivity with respect to the light emitted by the light emission unit 130. A material configuring the first electrode 120 and the second electrode 140, for example, is an inorganic material such as Indium Thin Oxide (ITO) or indium zinc oxide (IZO), or a conductive polymer material such as a polythiophene derivative. However, the first electrode 120 and the second electrode 140 may be a thin metal film which is thin to the extent that light is transmitted. The first electrode 120 and the second electrode 140 are connected to the control unit 300.

Next, the light transmission quantity adjustment unit 200 will be described. The light transmission quantity adjustment unit 200 includes the liquid crystal layer 210 and polarization units 232 and 234. The liquid crystal layer 210 is positioned between the polarization units 232 and 234. A polarization direction of the polarization unit 232 intersects with a polarization direction of the polarization unit 234. In addition, the liquid crystal layer 210 is interposed between a first electrode 222 and a second electrode 224. The first electrode 222 and the second electrode 224 are connected to the control unit 300. That is, the alignment direction of the liquid crystal in the liquid crystal layer 210 is controlled by the control unit 300.

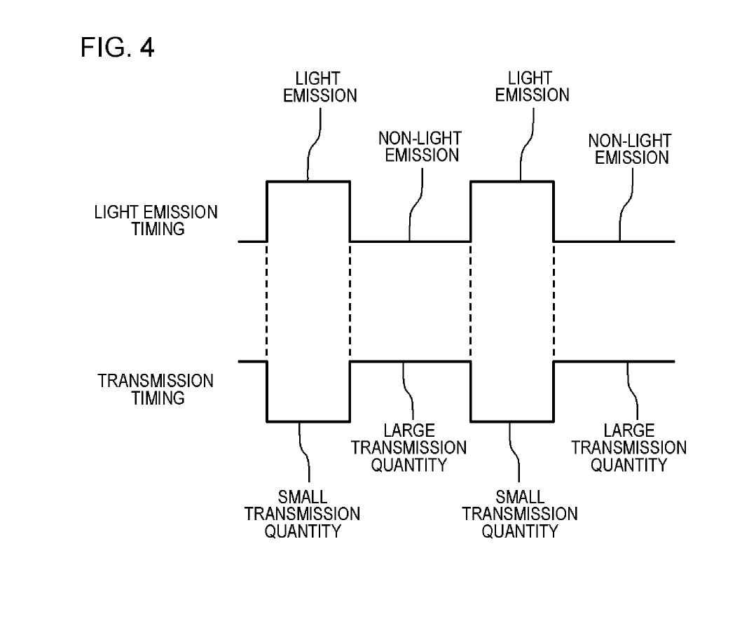

FIG. 4 is a diagram illustrating a first example of controlling the light transmission quantity adjustment unit 200 by the control unit 300. In an example of this drawing, the control unit 300 decreases the light transmission quantity of the light transmission quantity adjustment unit 200 (preferably, to be a minimum value, for example, less than or equal to 5%) at a timing of emitting the light by the surface light emission unit 100, and increases the light transmission quantity of the light transmission quantity adjustment unit 200 (preferably, to be maximized) at a timing other than the timing of emitting the light. According to this, at a timing at which the surface light emission unit 100 does not emit the light, a person is able to recognize the background of the surface light emission unit 100 from both of the first surface side and the second surface side of the light transmissive substrate 110. In addition, it is possible to suppress the light from the surface light emission unit 100 being emitted to the first surface side of the light transmissive substrate 110. Then, the person on the first surface side of the light transmissive substrate 110 will be hardly conscious of the existence of the surface light emission unit 100.

Further, when the surface light emission unit 100 is blinked at greater than or equal to 30 Hz, the person on the second surface side of the light transmissive substrate 110 is able to recognize that the surface light emission unit 100 continuously emits the light.

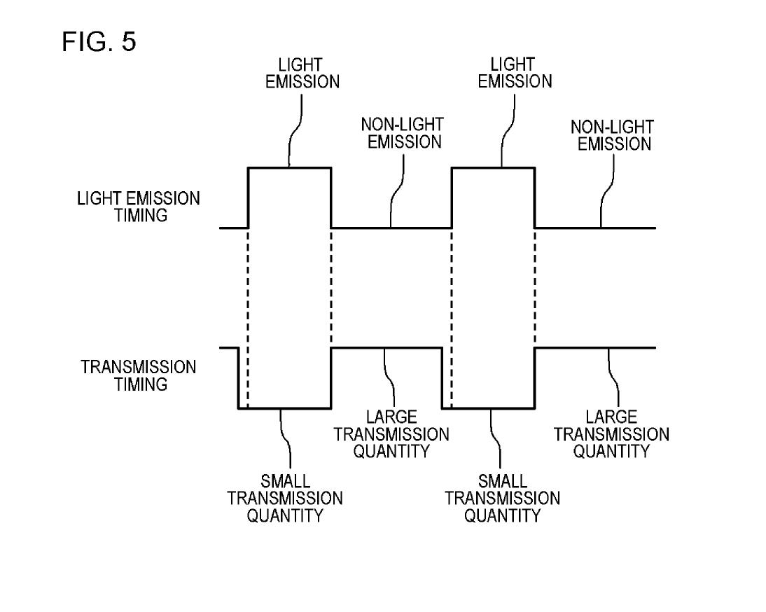

FIG. 5 is a diagram illustrating a second example of controlling the light transmission quantity adjustment unit 200 by the control unit 300. An example of this drawing is identical to the example illustrated in FIG. 4 except that the control unit 300 decreases the light transmission quantity of the light transmission quantity adjustment unit 200 (preferably, to be a minimum value, for example, less than or equal to 5%) before a timing of starting the light emission of the surface light emission unit 100. According to this, for example, even when a period of time is required after a signal is input and before the alignment direction of the liquid crystal is changed, it is possible to prevent the light from being emitted from the second surface side of the light transmissive substrate 110.

According to this example, the light transmission quantity adjustment unit 200 includes the liquid crystal layer 210 and the polarization units 232 and 234. For this reason, the control unit 300 is able to easily control light transmittance of the light transmission quantity adjustment unit 200.

### Example 2

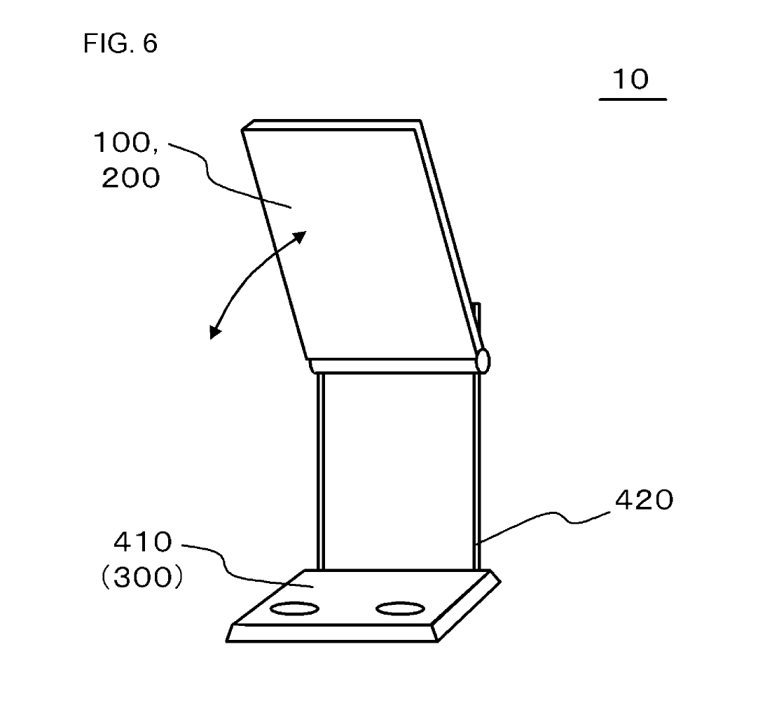

FIG. 6 is a diagram illustrating a configuration of the light emitting device 10 according to Example 2. The light emitting device 10 according to this embodiment is a stand for illumination, and includes a pedestal 410 and a support member 420. The support member 420 vertically extends, and supports the surface light emission unit 100 and the light transmission quantity adjustment unit 200 to be vertically slidable. In addition, the pedestal 410 is attached to a lower portion of the support member 420, and includes the control unit 300 inside.

According to this example, the surface light emission unit 100 and the light transmission quantity adjustment unit 200 are used as a light source of the stand, and thus the person on a back side of the surface light emission unit 100 (that is, the first surface side of the light transmissive substrate 110) does not need to be conscious of the light of the stand. In addition, a user of the stand is able to look at the sight of a back surface side of the surface light emission unit 100 while the surface light emission unit 100 is not emitting the light.

Furthermore, in the drawings using each example described above, the position of the light transmission quantity adjustment unit 200 with respect to the surface light emission unit 100 is the position illustrated in Embodiment 1. However, in these examples, the light transmission quantity adjustment unit 200 may be in the position illustrated in Embodiment 2.

As described above, the embodiments and the examples are described with reference to the drawings, but these embodiments and examples are exemplifications of the present invention, and various configurations other than the configuration described above are able to be adopted.

1. A light emitting device, comprising:
a light transmissive layer;
a light emission unit which is formed on a first surface side of the light transmissive layer;
a light transmission quantity adjustment unit which is disposed on a side opposite to the light transmissive layer based on the light emission unit, and adjusts a light transmission quantity according to a signal input from the outside; and
a light extraction layer which is disposed on a second surface side of the light transmissive layer.

2. The light emitting device according to claim 1, further comprising a control unit which controls the light transmission quantity adjustment unit based on a timing at which the light emission unit emits light.

3. A light emitting device, comprising:
a light-transmissive surface light emission unit;
a light transmission quantity adjustment unit which is disposed on one surface side of the surface light emission unit, and controls emission of light from the surface light emission unit; and
a control unit which controls the light transmission quantity adjustment unit based on a timing at which the surface light emission unit emits the light.

4. The light emitting device according to claim 2,
wherein the control unit decreases the light transmission quantity of the light transmission quantity adjustment unit at the timing of emitting the light.

5. The light emitting device according to claim 4,
wherein the control unit increases the light transmission quantity of the light transmission quantity adjustment unit at a timing other than the timing of emitting the light.

6. The light emitting device according to claim 4,
wherein the control unit decreases the light transmission quantity of the light transmission quantity adjustment unit from before a start of the timing of emitting the light.

7. The light emitting device according to claim 1,
wherein the light transmission quantity adjustment unit includes
two polarization layers, and
a liquid crystal layer positioned between the two polarization layers.

8. The light emitting device according to claim 3, further comprising:
a support member which supports the surface light emission unit and the light transmission quantity adjustment unit; and
a pedestal which is attached to a lower portion of the support member.
